(19) United States
(12) Patent Application Publication
(10) Pub. No.: US 2023/0031662 A1
(43) Pub. Date: Feb. 2, 2023

(54) III NITRIDE SEMICONDUCTOR WAFERS

(71) Applicant: INNOSCIENCE (SUZHOU) TECHNOLOGY CO., LTD., (US)

(72) Inventors: Kye Jin LEE, Suzhou City (CN); Ke WANG, Suzhou City (CN); Wen-Yuan HSIEH, Suzhou City (CN); Xinhua LI, Suzhou City (CN)

(21) Appl. No.: 17/417,394

(22) PCT Filed: Apr. 2, 2021
(86) PCT No.: PCT/CN2021/085441

§ 371 Date: Jun. 23, 2021

(51) Int. Cl. C30B 25/18; H01L 23/31; H01L 23/00; H01L 29/20; H01L 29/34; H01L 29/778; H01L 21/02; C30B 29/40

(52) U.S. Cl. CPC C30B 25/186; H01L 23/3171; H01L 23/562; H01L 29/2003; H01L 29/34; H01L 29/7786; H01L 21/02381; H01L 21/0243; H01L 21/02458; H01L 21/0251; H01L 21/0254; H01L 21/0262; C30B 25/183; C30B 29/406

(57) ABSTRACT

A III-nitride-based semiconductor wafer is provided that includes a substrate with a central region and a peripheral edge region. One or more intermediate layers may be optionally provided selected from a buffer layer, a seed layer, or a transition layer. A peripheral edge feature is formed in or on a peripheral edge region of the substrate or the transition layer, with one or more peripheral edge passivation layers or peripheral edge surface texturing. The peripheral edge feature extends only around the peripheral edge and not in the central region. One or more III-nitride-based layers is positioned over the central region. In the central region, the III-nitride layer is an epitaxial layer while in the peripheral edge region, it is a polycrystalline layer. Stress due to lattice mismatches and differences in the coefficient of thermal expansion between the III-nitride layer and the substrate is relieved, minimizing defects.

### FIELD OF THE INVENTION

The present invention generally relates to a III nitride-based semiconductor wafer, and more particularly, to improved III nitride layers formed on a substrate with peripheral edge features to prevent III nitride layer defects in a central region.

### BACKGROUND OF THE INVENTION

In recent years, research and development has focused on III nitride-based semiconductor materials for use in a variety of III nitride-based devices. III nitride-based devices include heterostructure-including devices, light emitting diodes (LEDs), and lasers. Examples of devices having heterostructures include heterojunction bipolar transistors (HBT), heterojunction field effect transistors (HFET), high-electron-mobility transistors (HEMT), or modulation-doped FETs (MODFET). As used herein, the term “III-nitride” means GaN, AlN, InN and various mixtures thereof such as AlGaN, InAlGaN and InAlN with various ratios of metal elements in the nitrides.

In order to produce low cost III nitride devices on a commercial scale, it is desirable to form III nitride layers on low cost semiconductor substrates such as silicon. However, there is a large lattice parameter mismatch between III nitride films such as gallium nitride (GaN) films and silicon substrates. There is approximately a 17% difference in the lattice parameter between silicon and GaN at room temperature and a 40% difference in the lattice parameter at about 800° C. The thermal expansion of silicon is approximately 50% lower than that of GaN; therefore, strong expansion stresses form in epitaxial GaN layers they cool down from high fabrication temperature to room temperature, leading to large tensile stresses in the deposited layer. These stresses lead to cracking of GaN layers, particularly for thick layers of greater than 1 micron; this problem is particularly pronounced for large diameter wafers.

In order to reduce the stresses caused by the mismatch in of thermal expansion and lattice mismatch, one or more intermediate layers are often interposed between the substrate and an epitaxial III nitride layer. However, even the use of various intermediate layers cannot fully prevent defects in the epitaxial layer, particularly for large silicon wafers (e.g., 6 inch or greater diameter silicon wafers). For example, FIG. 6 shows a prior art 8-inch silicon wafer with a GaN layer formed on a buffer layer. As seen in FIG. 6, there are peripheral edge cracks as well as slip planes caused by dislocations.

Further, the stresses in large wafers may cause substrate wafer warpage.

Currently, there is a need to improve III-nitride layers on substrates to reduce cracking and defects in epitaxial layers deposited on substrates.

### SUMMARY OF THE INVENTION

In accordance with one aspect of the present disclosure, a III-nitride-based semiconductor wafer is provided that includes a substrate including a central region and a peripheral edge region surrounding the central region. One or more intermediate layers may optionally be provided on the substrate, the one or more intermediate layers being selected from one or more of a buffer layer, a seed layer, or a transition layer. A peripheral edge feature is formed in or on a peripheral edge region of the substrate (or in or on the optional intermediate layer(s)), the peripheral edge feature comprising one or more peripheral edge passivation layers or peripheral edge surface texturing in or on the peripheral edge region of the substrate. The peripheral edge feature extends only around the peripheral edge and not in the central region within the peripheral edge. One or more III nitride-based layers is positioned over the central region. In the central region, the III-nitride layer is an epitaxial layer. In the peripheral edge region, the III-nitride layer is a polycrystalline layer. In this manner, stress due to lattice mismatches and differences in the coefficient of thermal expansion between the III nitride layer and the substrate is relieved, minimizing defects in the epitaxial portion of the III nitride layer and reducing or eliminating edge cracking in the III nitride layer.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

Embodiments of the invention are described in more detail hereinafter with reference to the drawings, in which:

FIGS. 1A-1G are cross-sectional views of a III nitride semiconductor wafer and its formation according to some embodiments of the present disclosure;

FIGS. 2A-2F are cross-sectional views of a III nitride semiconductor wafer and its formation according to further embodiments of the present disclosure;

FIGS. 3A-3F are cross-sectional views of a III nitride semiconductor wafer and its formation according to further embodiments of the present disclosure;

FIGS. 4A-4B are cross-sectional views of III nitride semiconductor wafers with device regions formed thereon;

FIG. 5 is a cross-section view of a semiconductor device according that can be formed in the device regions of FIGS. 4A-4B.

FIG. 6 is a top view of a prior art III nitride semiconductor wafer showing cracking and other defects.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

In the following description, semiconductor devices, methods for manufacturing the same, and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

The present invention provides improved III-nitride layers on substrates through peripheral edge features formed on a substrate. The peripheral edge features cause the formation of a stress-relieving polycrystalline III nitride layer in the peripheral edge of the III nitride film. In the central region of the film, an epitaxial III-nitride layer is formed. In this manner, stress cracks are prevented from forming and devices may be formed in or over the epitaxial portion of the III-nitride layer.

In a first aspect, the peripheral edge feature is a passivation layer formed only in the peripheral edge region of the substrate. In a further aspect a surface texturing that may be performed through selective etching to produce a stress-relieving surface texture. In general, the peripheral edge region is selected to be approximately 3 microns to 5 microns from the substrate edge (including the bevel edge when the substrate is a silicon substrate with a beveled edge).

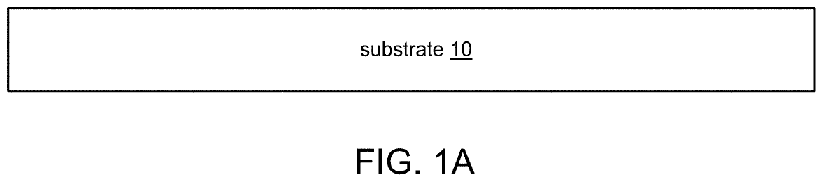

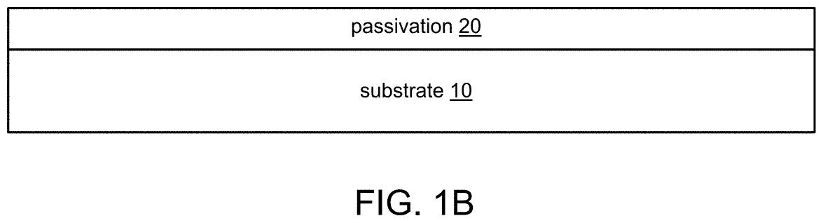

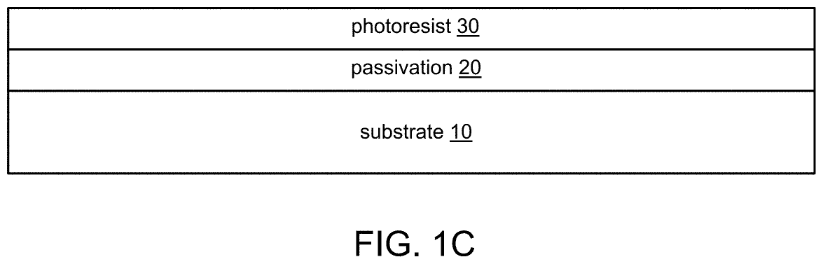

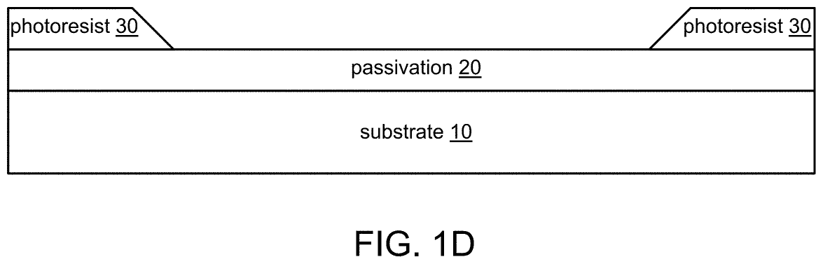

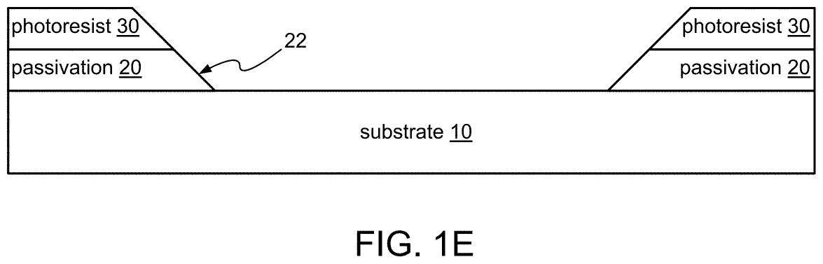

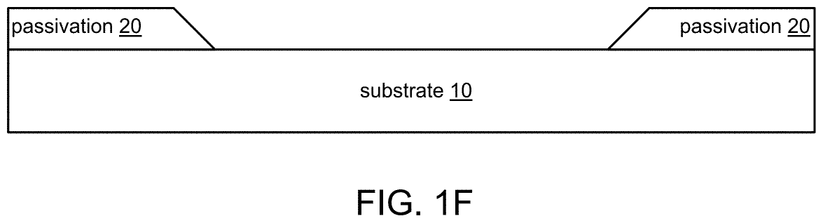

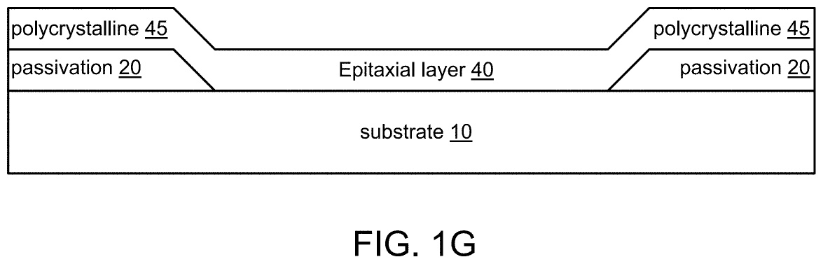

Turning to FIGS. 1A-1G, the first technique for forming a peripheral edge feature is depicted. In FIG. 1A, a substrate 10 is provided. In one embodiment, the substrate 10 is a large-diameter (equal to or greater than 6 inches) silicon wafer. In other embodiments, the substrate 10 is a sapphire wafer, a silicon carbide wafer, a GaN wafer, or SiGe, SiC, gallium arsenide, p-doped Si, n-doped Si, semiconductor on insulator, such as silicon on insulator (SOI), or other suitable semiconductor materials including group III elements, group IV elements, group V elements, or combinations thereof.

In one embodiment, the substrate 10 may optionally include an intermediate layer that may be a buffer layer, transition layer, seed layer or other layer between the base substrate and the III-nitride layer formed thereon. This optional layer may be one or more of nitrides or group III-V compounds, such as GaN, GaAs, InN, AlN, InGaN, AlGaN, InAlGaN, or combinations thereof. Further, various transitional structures such as superlattices of AlN/GaN and AlGaN/GaN may be used.

To form the peripheral edge passivation layer, a blanket passivation film 20 may be deposited on substrate 10 (or optional intermediate layer if present) as seen in FIG. 1B. The blanket passivation layer may be an oxide, nitride, or oxynitride layer of silicon, aluminum, or mixtures thereof such as silicon dioxide, silicon nitride, silicon oxynitride. In one aspect the layer is silicon dioxide formed by oxidation of silicon substrate or deposition by chemical vapor deposition, plasma-enhanced chemical vapor deposition, sputtering, or evaporation. The thickness of the passivation layer may be 50 nm to 1000 nm.

In FIG. 1C a layer of photoresist 30 is deposited over the surface through any known technique such as spray coating or spin coating. A mask is used to define a pattern including a central region and peripheral edge region. The photoresist 30 is exposed (in a positive or negative pattern depending on the selected photoresist) to radiation such as ultraviolet radiation or other radiation to expose the selected pattern. Following exposure, the undesired portion is removed with a developer, leaving the peripheral photoresist pattern of FIG. 1D.

Using the peripheral photoresist of FIG. 1D as a mask, the passivation layer 20 in the central region is removed by etching. Various wet or dry etching techniques may be used depending upon the selected passivation material. Wet etching, for example, with nitric or hydrofluoric acid, tends to be isotropic in nature, therefore dry etching may be preferable for anisotropic removal of the passivation layer 20 in the region not protected by patterned photoresist 30. Dry etching may be a plasma-based etch using reactive gases such as CCl₄, CF₄, SF₆, NF₃, or CCl₂F₂. Photoresist patterning may result in an angled edge profile (FIG. 1E) that assists in the transition between an epitaxial region of a III-nitride layer to be formed in the central region and a polycrystalline region of a III-nitride layer to be formed in the peripheral edge region.

Following etching, the structure of FIG. 1E results, with the passivation layer 20 remaining only in the peripheral region of the substrate. The photoresist is removed using a resist stripper or other known techniques such as oxygen plasma, in FIG. 1F leaving only the passivation layer 20 in the peripheral region.

A III-nitride layer is deposited over the structure of FIG. 1F using, for example, high temperature chemical vapor deposition or plasma-enhanced chemical vapor deposition. To deposit III-nitride films, a nitrogen source such as nitrogen, ammonia, or other nitrogen-containing gases is provided along with one or more Group III sources such as indium, gallium, or aluminum. Exemplary Group III sources include organometallic gases such as trimethyl indium, trimethyl gallium, or trimethyl aluminum. Optionally, carrier gases such as hydrogen or nitrogen may be provided for the organometallic gases. Depending upon the selected reactants, an organometallic gas may decompose upon being heated into an intermediate produce. This intermediate product will react with the nitrogen source gas (such as ammonia) and form a III-nitride layer on the substrate. Additional gases may be added for dopants that are introduced during the film formation process (e.g., sources for dopants such as magnesium, iron, silicon, fluorine, etc.). The deposited material may be any HI-nitride with examples including GaN, AlN, InN, In_{X}Al_{y}Ga_{(1-x-y)}N where x+y≤1, Al_{y}Ga_{(1-y)}N where y≤1.

As seen in FIG. 1G, an epitaxial III-nitride layer is formed in the central region over the substrate 10 and any optional intermediate transition layers. In the peripheral region over the passivation layer 20, a polycrystalline III-nitride layer 45 is formed. The combination of these two crystal structures alleviates forming stresses, reducing film cracking in the periphery and reducing defects in the central epitaxial region. As will be discussed in further detail below, further III-nitride layers may be deposited over the epitaxial layer 40 and devices formed over this central region. As will be appreciated, for large substrate wafers 10, large numbers of devices are formed above the central region, followed by separation to form individual III-nitride devices.

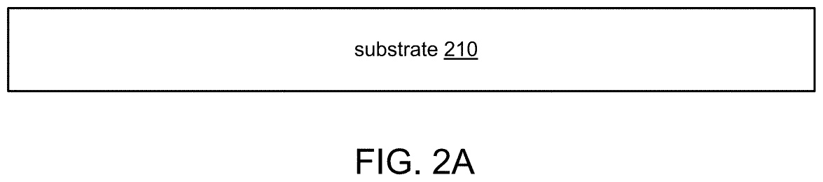

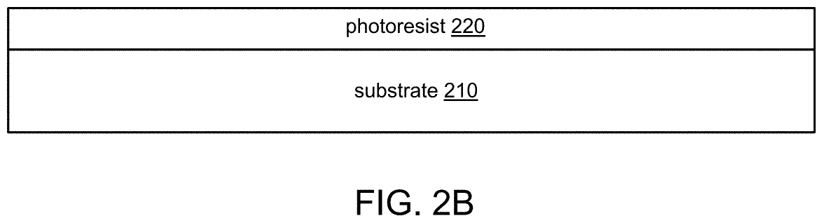

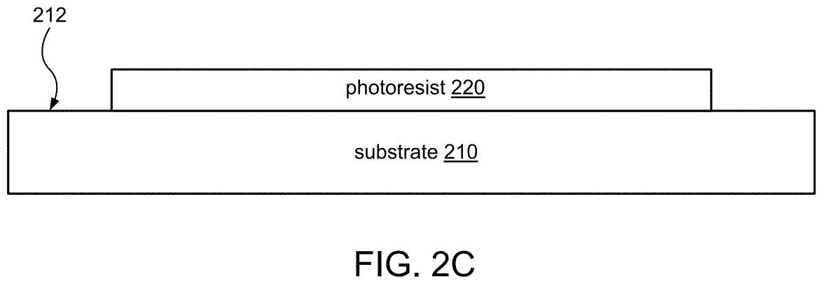

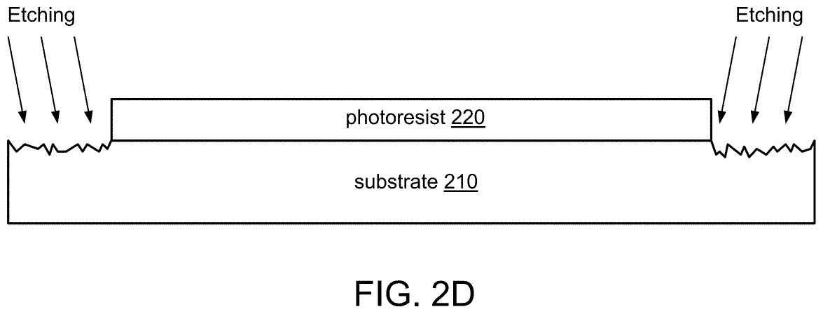

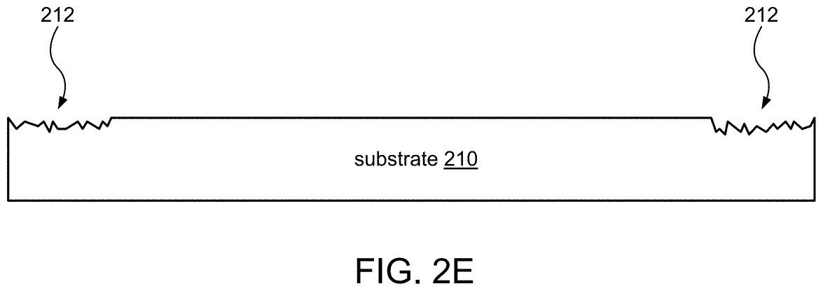

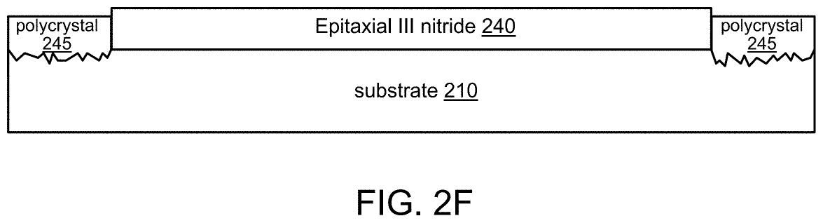

Turning to FIGS. 2A-2G, a further technique for forming a peripheral edge feature is depicted. In FIG. 2A, a substrate 210 is provided which may be an epitaxial large-diameter substrate (equal to or greater than 6 inches) silicon wafer. In other embodiments, the substrate 210 is a sapphire wafer, a silicon carbide wafer, a GaN wafer, or SiGe, SiC, gallium arsenide, p-doped Si, n-doped Si, semiconductor on insulator, such as silicon on insulator (SOI), or other suitable semiconductor materials including group III elements, group IV elements, group V elements, or combinations thereof.

The substrate 210 may optionally include an intermediate layer such as a buffer layer, transition layer, seed layer or other layer between the base substrate and the III-nitride layer formed thereon. This optional layer may be one or more of nitrides or group III-V compounds, such as GaN, GaAs, InN, MN, InGaN, AlGaN, InAlGaN, or combinations thereof. Further, various transitional structures such as superlattices of AlN/GaN and AlGaN/GaN may be used.

To form the peripheral edge passivation layer, a blanket photoresist layer 220, shown in FIG. 1B may be deposited on substrate 210 (or on the optional intermediate layer) through any known technique such as spray coating or spin coating. A mask is used to define a pattern including a central region and peripheral edge region. The photoresist 220 is exposed to radiation such as ultraviolet radiation or other radiation to expose the selected pattern. Following exposure, the undesired portion in the peripheral edge region 212 is removed with a developer, leaving the peripheral photoresist pattern of FIG. 2C.

A surface texturing process is performed in peripheral edge region 212. In the embodiment shown in FIG. 21), an etching process is performed to create surface roughness. As will be seen in the embodiments described below, the surface texturing may also be selected to produce a regular pattern in substrate 210. Various wet or dry etching techniques may be used depending upon the desired surface texturing. Wet etching, for example, with nitric/hydrofluoric acid, may be used which, being isotropic, will texturing along various silicon planes depending on the substrate orientation. Dry etching may be used (e.g., reactive ion etching) such as a plasma-based etch using reactive gases such as CCl₄, CF₄, SF₆, NF₃, or CCl₂F₂. Sputter etching may also be used. Etching is performed until etch pits have a depth of approximately 3-7 microns, with 5 microns being an example.

Following etching, the photoresist covering the central region of the substrate 210 is removed using a resist stripper or other known techniques such as oxygen plasma, leaving only the substrate 210 with etched peripheral region 212.

A III-nitride layer is deposited over the structure of FIG. 2E using, for example, high temperature chemical vapor deposition or plasma-enhanced chemical vapor deposition, as discussed above.

As seen in FIG. 2F, an epitaxial III-nitride layer 240 is formed in the central region over the substrate 210 and any optional intermediate transition layers. In the peripheral region over the etched substrate peripheral region, a polycrystalline RI-nitride layer 245 is formed. The combination of these two crystal structures alleviates forming stresses, reducing film cracking in the periphery and reducing defects in the central epitaxial region.

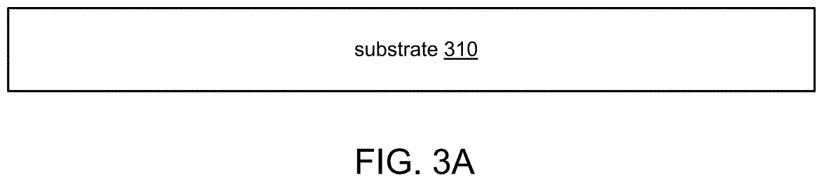

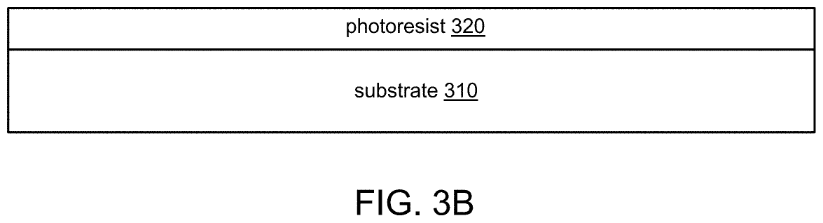

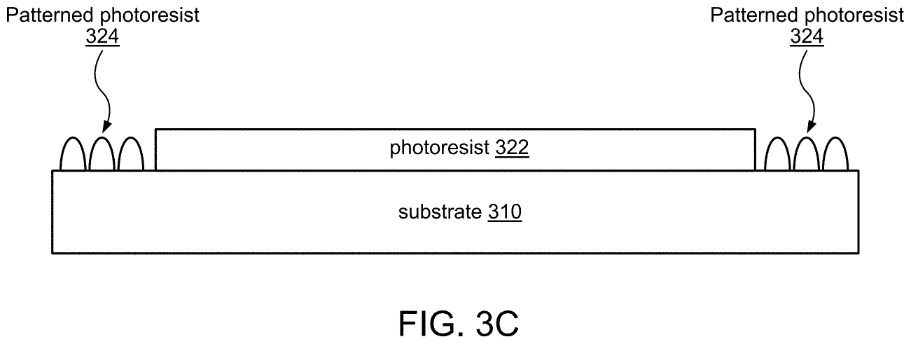

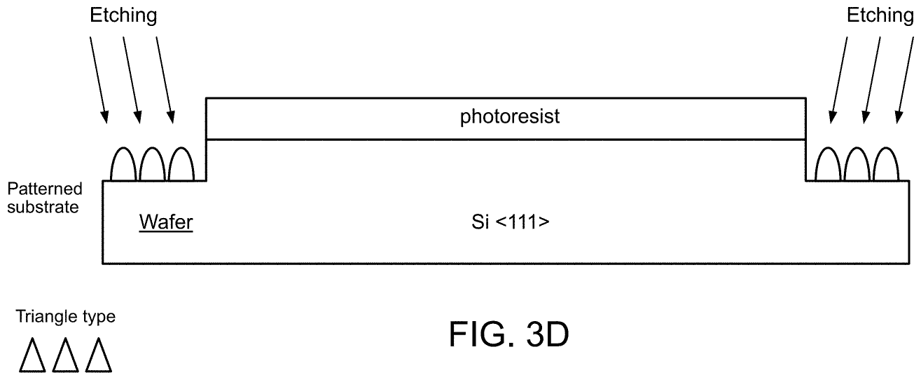

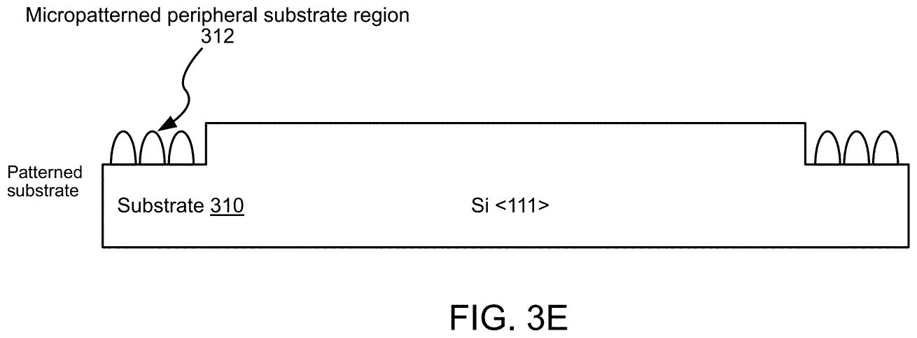

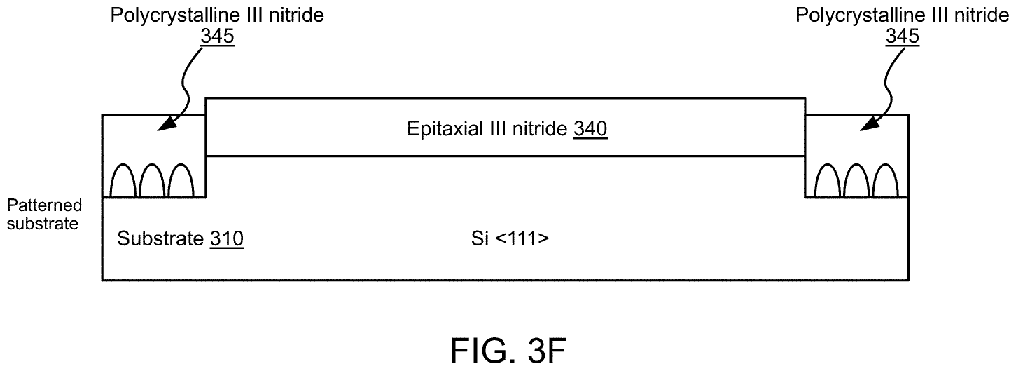

In an alternative embodiment of FIGS. 3A-3F, the substrate may be micropatterned to create a more regular surface micropatterned structure than the etching embodiment of FIGS. 2A-2F. In FIGS. 3A-3B a substrate 310 and photoresist layer 320 are provided, as in the embodiment of FIGS. 2A-2F.

In FIG. 3C, the photoresist is patterned using a mask or maskless process to provide coverage in the central region 322 and a patterned structure 324 in the peripheral region. The depth of the micropatterned features is approximately 2-4 microns.

Wet or dry etching is performed in FIG. 3D using the photoresist as an etching mask. The etchants used may be those described above. A variety of patterns may be formed such as a domed pattern or a triangular pattern depending upon the photoresist micropattern and depending upon the selectivity of the etchant, for example, 70 degree angular planes exposed by a selective etchant on a <111> silicon substrate.

Following etching, a micropatterned substrate peripheral region 312 is formed as seen in FIG. 3E. A HI-nitride layer is deposited over the structure of FIG. 3E using, for example, high temperature chemical vapor deposition or plasma-enhanced chemical vapor deposition, as discussed above.

As seen in FIG. 3F, an epitaxial HI nitride layer 340 is formed in the central region over the substrate 310 and any optional intermediate transition layers. In the peripheral region over the micropatterned substrate peripheral region 312, a polycrystalline III nitride layer 345 is formed. The combination of these two crystal structures alleviates deposition stresses, reducing film cracking in the periphery and reducing defects in the central epitaxial region.

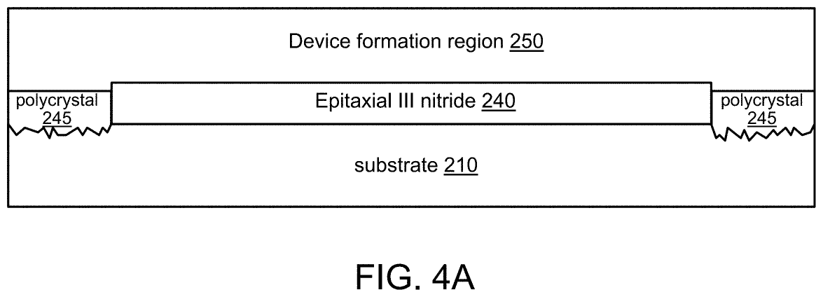

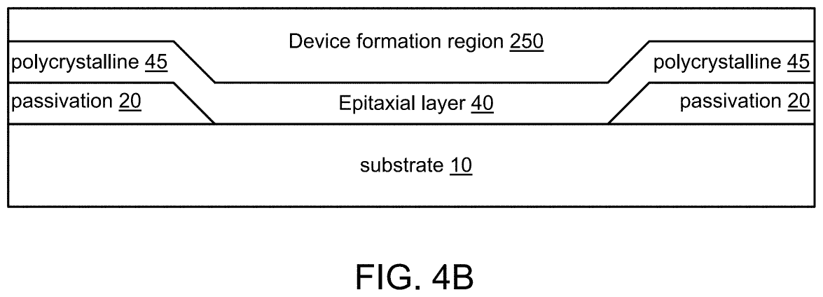

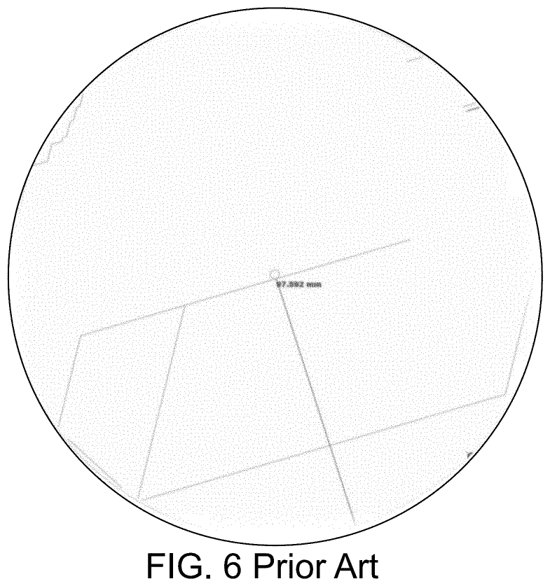

The III-nitride wafers formed according to the present invention may be used as the basis for one or more III-nitride devices formed in or above the central epitaxial III nitride layers formed over the substrates. In FIGS. 4A-43, the device formation region is central region 250 and 50 respectively.

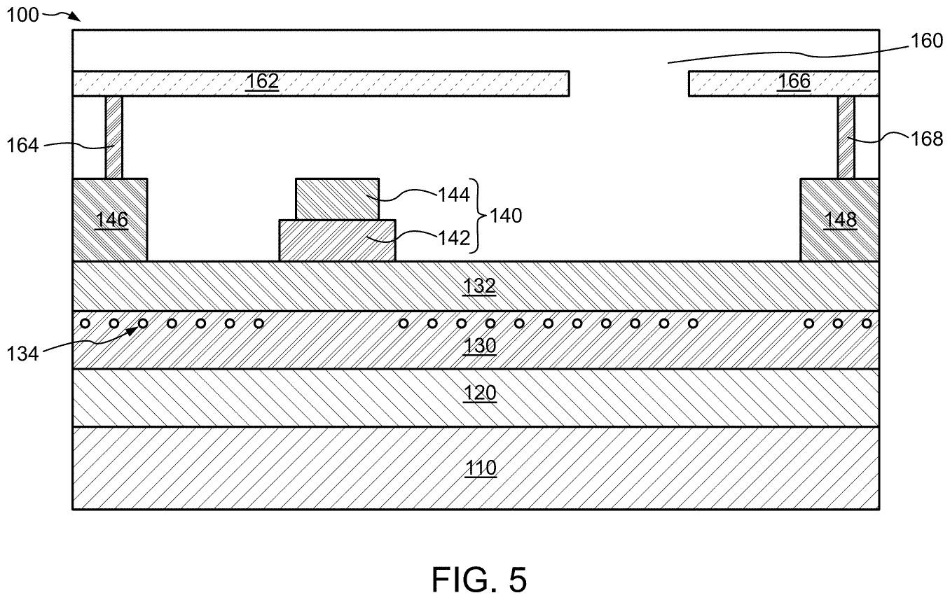

FIG. 5 is an example of a type of III-nitride device that may be formed in central regions 250 and 50. FIG. 5 is a cross-sectional view of a semiconductor device 100 that may be formed in the central region over the epitaxial III-nitride layer The semiconductor device 100 includes a substrate 110, an optional buffer layer 120, a semiconductor layer 130 (that may correspond to the epitaxial portion of the III-nitride layer described above), a semiconductor layer 132, a gate structure 140, a source 146, a drain 148.

The exemplary materials of the semiconductor layers 130 and 132 are selected such that the semiconductor layer 132 has a bandgap (i.e., forbidden band width) greater than a bandgap of the semiconductor layer 130, which causes electron affinities thereof different from each other. For example, when the semiconductor layer 130 is an undoped GaN layer having bandgap of approximately 3.4 eV, the semiconductor layer 132 may be an AlGaN layer having bandgap of approximately 4.0 eV. As such, the semiconductor layers 130 and 132 serve as a channel layer and a barrier layer, respectively. A triangular well potential is generated at a bonded interface between the channel and barrier layers, so that electrons accumulate in the triangular well potential, thereby generating a two-dimensional electron gas (2DEG) region 134 at the same interface. Accordingly, the semiconductor device 100 can serve as a high-electron-mobility transistor (HEMT).

A gate structure 140 is disposed on the semiconductor layer 132. In the present embodiment, the gate structure 140 includes a p-type doped III-V compound layer/nitride semiconductor layer 142 forming an interface with the semiconductor layer 132 and a conductive gate 144 stacked on the p-type doped III-V compound/nitride semiconductor layer 132. In other embodiments, the gate structure 140 may further include a dielectric structure (not illustrated) between the p-type doped III-V compound/nitride semiconductor layer 142 and the conductive gate 144, in which the dielectric structure can be formed by one or more layers of dielectric materials.

In the embodiment of FIG. 5 the semiconductor device 100 is an enhancement mode device, which is in a normally-off state when the conductive gate 144 is at approximately zero bias. Specifically, the p-type doped III-V compound/nitride semiconductor layer 142 creates a p-n junction with the semiconductor layer 132 to deplete the 2DEG region 134, such that a zone of the 2DEG region 134 corresponding to a position below the gate structure 140 has different characteristics (e.g., different electron concentrations) than the rest of the 2DEG region 134 and thus is blocked.

Due to such mechanism, the semiconductor device 100A has a normally-off characteristic. In other words, when no voltage is applied to the gate 144 or a voltage applied to the gate 144 is less than a threshold voltage (i.e., a minimum voltage required to form an inversion layer below the gate structure 140), the zone of the 2DEG region 134 below the gate structure 140 is kept blocked, and thus no current flows there through. Moreover, by providing the p-type doped III-V compound/nitride semiconductor layer 142, gate leakage current is reduced and an increase in the threshold voltage during the off-state is achieved.

The exemplary material of the p-type doped III-V compound layer 142 can include, for example but is not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd. In one embodiment, the semiconductor layer 130 includes undoped GaN and the semiconductor layer 132 includes AlGaN, and the p-type doped III-V compound layer 142 is a p-type GaN layer which can bend the underlying band structure upwards and to deplete the corresponding zone of the 2DEG region 134, so as to place the semiconductor device 100A into an off-state condition. Alternatively, the gate 144 may be deposited directly on the layer 132, resulting in a normally-on device.

The exemplary material of the conductive gate 144 may be metals or metal compounds including, but not limited to W, Au, Pd, Ti, Ta, Co, Ni, Pt, Mo, TiN, TaN, other metallic compounds, nitrides, oxides, silicides, doped semiconductors, metal alloys, or combinations thereof. The optional dielectric structure can include, for example but is not limited to, one or more oxide layers, a SiO_{X} layer, a SiN_{X} layer, a high-k dielectric material (e.g., HfO₂, Al₂O₃, TiO₂, HfZrO, Ta₂O₃, HfSiO₄, ZrO₂, ZrSiO₂, etc.), or combinations thereof.

The source 146 and the drain 148 are disposed on the semiconductor layer 132 and located at two opposite sides of the gate structure 140 (i.e., the gate structure 140 is located between the source 146 and the drain 148). In the exemplary illustration of FIG. 5, the source 146 and the drain 148 are asymmetrical about the gate structure 140, with the source 146 closer to the gate structure 140 than the drain 148. The present disclosure is not limited thereto, and the configuration of the source 146 and the drain 148 is adjustable. The exemplary materials of the source 146 and the drain 148 can include, for example but is not limited to, metals, alloys, doped semiconductor materials (such as doped crystalline silicon), other conductor materials, or combinations thereof.

Optional additional p-doped regions may be provided beneath or next to the drain electrode as disclosed in U.S. Pat. No. 10,833,159, the disclosure of which is incorporated by reference herein.

The semiconductor device 100 further includes one or more dielectric layer(s) 160 disposed on the semiconductor layer 132 and covering the gate structure 140. In some embodiments, the dielectric layer 160 serves as a passivation layer to protect the underlying elements or layers. In various embodiments, the dielectric layer 160 has a flat topmost surface, which is able to act as a flat base for carrying layers formed in a step subsequent to the formation of the dielectric layer 160. The exemplary material of the dielectric layer 160 can include, for example but is not limited to, SiN_{X}, SiO_{X}, SiON, SiC, SiBN, SiCBN, oxides, nitrides, or combinations thereof. In some embodiments, the dielectric layer 160 is a multi-layered structure, such as a composite dielectric layer of Al₂O₃/SiN, Al₂O₃/SiO₂, AlN/SiN, AlN/SiO₂, or combinations thereof.

The semiconductor device 100 further optionally includes a source field plate 162 disposed over the source 146, a first via 164 between the source field plate 162 and the source 146, a drain field plate 166 disposed over the drain 148, and a second via 168 between the drain field plate 166 and the drain 148, in which the source and drain field plates 162 and 166 are higher than the gate structure 140 with respect to the second semiconductor layer 132.

The source field plate 162 extends from a position above the source 146 to and over a position above the gate structure 140. In some embodiments, the source field plate 162 has an extending length greater than a distance from the source 146 to the gate structure 140. That is, a vertical projection of the gate structure 140 on the semiconductor layer 132 is present within a vertical projection of the source field plate 162 on the semiconductor layer 132. The first via 164 connects the source 146 and the source field plate 162, such that the source 146 and the source field plate 162 are electrically coupled with each other.

The drain field plate 166 extends from a position above the drain 148 toward the position above the gate structure 140. In some embodiments, the drain field plate 166 has an extending length less than a distance from the drain 148 to the gate structure 140. That is, a vertical projection of the gate structure 140 on the semiconductor layer 132 is out of a vertical projection of the drain field plate 166 on the semiconductor layer 132. The second via 168 connects the drain 148 and the drain field plate 166, such that the drain 148 and the drain field plate 166 are electrically coupled with each other.

These source and drain field plates 162 and 166 change an electric field distribution of the source and drain regions and affect breakdown voltage of the semiconductor device 100. In other words, the source and drain field plates 162 and 166 suppress the electric field distribution in desired regions and to reduce its peak value. The exemplary materials of the source and the drain field plates 162 and 166 can include, for example but are not limited to, metals, alloys, doped semiconductor materials (such as doped crystalline silicon), other suitable conductor materials, or combinations thereof.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive.

Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A III-nitride-based semiconductor wafer comprising:
a substrate wafer, the substrate including a central region and a peripheral edge region surrounding the central region;
a peripheral edge feature formed in or on a peripheral edge region of the substrate, the peripheral edge feature comprising one or more peripheral edge passivation layers or peripheral edge surface texturing in or on the peripheral edge region of the substrate, the peripheral edge feature extending around the peripheral edge and not in the central region within the peripheral edge; and
one or more III-nitride-based layers positioned over the central region and over the peripheral edge region such that a portion of the layers III nitride-based layer over the central region is an epitaxial III-nitride and a portion of the III-nitride-based layer over the peripheral edge region is a polycrystalline III nitride.

2. The III nitride-based semiconductor wafer according to claim 1, wherein the substrate is silicon.

3. The III-nitride-based semiconductor wafer according to claim 1, wherein the III nitride is gallium nitride.

4. The III-nitride-based semiconductor wafer according to claim 1, further comprising one or more intermediate layers on the substrate beneath the one or

17. The method of fabricating a III-nitride-based semiconductor wafer according to claim 11, wherein the surface texturing comprises micropatterning a peripheral edge region of a top layer of the one or more intermediate layers formed on the substrate.

18. The method of fabricating a III-nitride-based semiconductor wafer according to claim 14, wherein the intermediate layer includes plural graded composition layers to reduce lattice mismatch between the substrate and the III nitride-based layer.

19. The method of fabricating a III-nitride-based semiconductor wafer according to claim 11, further comprising forming one or more semiconductor devices in or on the epitaxial portion of the one or more III-nitride layers.

20. The method of fabricating a III-nitride-based semiconductor wafer according to claim 19 wherein the one or more semiconductor devices is one or more gallium nitride-based high electron mobility transistors. more III-nitride-based layers, the one or more intermediate layers selected from one or more of a buffer layer, a seed layer, or a transition layer and wherein a peripheral edge feature is formed in at least one of the one or more intermediate layers.

5. The III-nitride-based semiconductor wafer according to claim 1, wherein the one or more III-nitride-based layers positioned over the peripheral edge feature and over the central region includes a first layer of gallium nitride.

6. The III-nitride-based semiconductor wafer according to claim 1, wherein the one or more passivation layers includes an oxide, nitride, or oxynitride layer.

7. The III-nitride-based semiconductor wafer according to claim 1, wherein the surface texturing includes an etched peripheral edge region.

8. The III-nitride-based semiconductor wafer according to claim 1, wherein the surface texturing includes a micropatterned peripheral edge region.

9. The III-nitride-based semiconductor wafer according to claim 4, wherein the intermediate layer includes plural graded composition layers to reduce lattice mismatch between the substrate and the III nitride-based layer.

10. The III-nitride-based semiconductor wafer according to claim 1, wherein one or more semiconductor devices are formed in or on the one or more III-nitride layers above the central portion of the substrate.

11. A method of fabricating a III-nitride-based semiconductor wafer comprising:
providing a substrate, the substrate including a central region and a peripheral edge region surrounding the peripheral edge region;
forming a peripheral edge feature in or on a peripheral edge region of the substrate, the peripheral edge feature comprising one or more peripheral edge passivation layers or surface texturing of the peripheral edge region, the peripheral edge feature extending around the peripheral edge and not in the central region within the peripheral edge;
depositing one or more III-nitride-based layers positioned over the peripheral edge feature and over the central region such that a portion of the III nitride-based layer above the central region of the substrate is epitaxial III nitride and a portion of the III-nitride-based layer above the peripheral edge feature is polycrystalline III-nitride.

12. The method of fabricating a III-nitride-based semiconductor wafer according to claim 11, wherein the substrate is silicon and forming the peripheral edge feature includes depositing a passivating layer on the silicon substrate, masking the passivating layer and removing a central region of the passivating layer, leaving a peripheral edge portion of the passivating layer to form the peripheral edge feature.

13. The method of fabricating a III-nitride-based semiconductor wafer according to claim 11, wherein the III-nitride is gallium nitride.

14. The method of fabricating a III-nitride-based semiconductor wafer according to claim 11, further comprising depositing one or more intermediate layers on the substrate beneath the one or more III-nitride-based layers, the one or more intermediate layers selected from one or more of a buffer layer, a seed layer, or a transition layer and wherein a peripheral edge feature is formed in at least one of the one or more intermediate layers.

15. The method of fabricating a III-nitride-based semiconductor wafer according to claim 11, wherein the one or more passivation layers includes an oxide, nitride, or oxynitride layer.

16. The method of fabricating a III-nitride-based semiconductor wafer according to claim 11, wherein the surface texturing comprises etching a peripheral edge region of a top layer of the one or more intermediate layers formed on the substrate.
